(19) United States
(12) Patent Application Publication
(10) Pub. No.: US 2025/0098553 A1
(43) Pub. Date: Mar. 20, 2025

(54) FERROELECTRIC TUNNEL JUNCTION WITH MULTILEVEL SWITCHING

(71) Applicant: INTERMOLECULAR, INC., SAN JOSE, CA (US)

(72) Inventors: RAISUL ISLAM, SAN JOSE, CA (US); MARIO LAUDATO, SAN JOSE, CA (US); RUBEN WALDMAN, BERKELEY, CA (US)

(21) Appl. No.: 18/291,551

(22) PCT Filed: Jul. 21, 2022
(86) PCT No.: PCT/US2022/073992

§ 371 Date: Jan. 23, 2024

Related U.S. Application Data
(60) Provisional application No. 63/225,400, filed on Jul. 23, 2021.

(51) Int. Cl. H10N 70/00; H10N 70/20

(52) U.S. Cl. CPC H10N 70/023; H10N 70/028; H10N 70/041; H10N 70/25; H10N 70/841; H10N 70/8833

(57) ABSTRACT

The disclosed and claimed subject matter relates to a ferroelectric tunnel junction that is BEOL compatible having a film comprising crystalline ferroelectric materials that include a mixture of hafnium oxide and zirconium oxide having a substantial (i.e., approximately 40% or more) or majority portion of the material in a ferroelectric phase as deposited (i.e., without the need for further processing, such as a subsequent capping or annealing) and methods for preparing and depositing these materials. An interfacial layer is formed by oxidizing one or more of a first electrode and a second electrode. The FTJ has a memory window of between about 2× and 10× and is stable over 4 resistance states for at least 10's. The FTJ is produced at temperatures less than or equal to 400 degrees Celsius.

### RELATED APPLICATIONS

This application claims priority to U.S. Provisional Patent application No. 63/225,400 filed on Jul. 23, 2021, which is hereby incorporated by reference.

### FIELD

The disclosed and claimed subject matter relates generally to ferroelectric materials deposited using vapor techniques, including atomic layer deposition (ALD). More specifically, the disclosed and claimed subject matter relates to ferroelectric tunnel junctions (FTJs) having thin film crystalline ferroelectric materials that include a mixture of hafnium oxide and zirconium oxide having a substantial (i.e., approximately 40% or more) portion of the material in a ferroelectric phase and methods for preparing and depositing these materials. Significantly, these materials exhibit ferroelectric properties without the need for further processing, such as a subsequent capping or annealing.

### BACKGROUND

Hafnium and zirconium oxide-based ferroelectric materials enable a variety of computing devices, including non-volatile memories and power-efficient logic devices, owing to their strong non-linear capacitance and remanent polarization. These materials may also be useful for a variety of other thermal and magnetic applications. Materials containing hafnium oxide and zirconium oxide are highly desirable for these applications owing to their compatibility with many CMOS fabrication processes and materials. They are also desirable owing to their ability to be deposited as thin films from the vapor phase, including by ALD processes involving the stepwise introduction and removal of a precursor followed by the introduction and removal of a reactant gas and other known processes (e.g., chemical vapor deposition (CVD) or pulsed CVD). Hafnium and zirconium oxide-based materials are polymorphic. Thus, their atoms can be arranged in several crystal structures (i.e., different ordered atomic arrangements). It is well known that the most stable bulk structure of hafnium and zirconium oxide-based materials is a monoclinic phase; however, this phase does not support ferroelectricity. Other polymorphs (e.g., some orthorhombic and rhombohedral phases) have the symmetry required to support ferroelectric switching behavior, while still others (e.g., a tetragonal phase common in zirconium oxide thin films) can be anti-ferroelectric-like. The listing of related art attached hereto identifies reference materials describing these general features and aspects of the art in more detail.

In many vapor and atomic layer deposition processes for mixed hafnium oxide and zirconium oxide materials, the materials are amorphous as deposited

Even with thermal treatment, crystallization into monoclinic or other non-ferroelectric phases is common, and thereby reduces the fraction of the material capable of ferroelectric behavior. Several techniques have been developed to suppress the monoclinic phase in favor of phases that can support ferroelectricity. For example, incorporating other elements (including but not limited to Si, Al, Gd, La, and Y) into the material by sequential or concomitant introduction of precursors for the other elements into the vapor phase has been reported as a means of suppressing the monoclinic phase.

One study has shown that thick films (ca. 30 nm) of hafnium and zirconium oxide can demonstrate weak ferroelectricity from a ferroelectric phase. See Y. Li et al., “A Ferroelectric Thin Film Transistor Based on Annealing-Free HfZrO Film,” in IEEE Journal of the Electron Devices Society, vol. 5, no. 5, pp. 378-383, September 2017, doi: 10.1109/JEDS.2017.2732166. It appears that this behavior comes about due to the reduction of surface energy effects as compared to thinner films and the prolonged exposure to heat, which acts as a functional equivalent to annealing, in order to generate a film of such thickness. However, this study acknowledges what is generally known in the art: that thin films (ca. 20 nm or less) will not exhibit ferroelectric behavior absent annealing at elevated temperatures (either alone or combined with doping) and the capping approaches mentioned above.

Therefore, obtaining a desired ferroelectric phase traditionally depends on a complicated and complex combination of (i) the deposition conditions of the material itself, (ii) the choice of dopants, interfaces, importantly the top interface and (iii) thermal treatments after deposition. As can be easily appreciated, this combination of factors places significant limitations on the usefulness of such materials with respect to possible substrates, interlayers, electrodes, compositions, and processes. Indeed, the thermal profile in devices implementing such ferroelectric materials may not be compatible with all necessary or desirable applications for which ferroelectric materials may be useful. For example, it has been observed that specific electrodes may be needed to modulate electronic work functions, that interfaces may be needed to create barrier layers against chemical reactions and atomic diffusion, and that thermal processing conditions may be limited by stresses introduced in other layers in a multilayer stack.

Ferroelectric tunnel junctions (FTJs) are two-terminal memory device where a ferroelectric material along with other interfacial dielectric material is sandwiched between two similar/dissimilar electrodes that stores the data based on the resistance switching of the device (i.e., low resistance and high resistance states indicate two distinct memory states and hence store one bit of information). The resistance change is initiated by the change in the tunneling barrier height between the two electrodes because of the switching of the orientation of permanent charge dipoles in the ferroelectric materials. Ferroelectric materials are typically crystalline/poly-crystalline materials that have permanent charge dipoles formed because of the asymmetry dipole charge centers inside the crystal lattice that are switchable by applying an electric field. Because of the permanent orientation switching of the dipoles, without an electric field such materials demonstrate a polarization (remnant polarization) that can change the direct tunnel barrier between the two electrodes.

Typically for an FTJ to work, an inherent asymmetry is needed between the two electrodes. This asymmetry can be achieved by two ways, (i) using two different types of contact materials for two electrodes (either two different metals or one metal and one semiconductor), (ii) using an interfacial dielectric material that is non-ferroelectric.

The basic idea of a Ferroelectric Tunnel Junction (FTJ) (called a polar switch at that time) may be attributed to Esaki et al. and was formulated in 1971. The FTJ has been extensively studied in literature in the last 10 years and several materials have been used such as Lead Zirconium Titanate-Pb (ZrₓTi₁₋ₓ)O₃(PZT), Bismuth Ferrite (BiFeO₃—BFO), Barium Titanate (BaTiO₃—BTO), Lanthanum Strontium Manganite (La_{0.67}Sr_{0.33}MnO₃—LSMO), organic polyvinylidene fluoride (PVDF) and organic Poly (Vinylidenefluoride-Trifluoroethylene)-P (VDF-TrFE). Due to poor BEOL process compatibility and integration complexity for these materials, hafnium oxide based FTJs have been recently deeply studied thanks to its good compatibility with CMOS process especially with certain dopant (Zr, Si) in order to improve ferroelectricity of the material. Use of interfacial layer (SiO₂, Al₂O₃, WOₓ) has been recently also introduced to introduce asymmetry within FTJ stack and increase the performance of the memory in terms of Tunneling Electro-resistance (TER) window and retention but still with results not sufficient to allow more than 2-3 memory level programming with acceptable retention for period longer than few hours.

### SUMMARY

In a first main aspect, the disclosed subject matter relates to a ferroelectric tunnel junction (FTJ) comprising: a substrate; a first electrode and a second electrode, wherein a portion of the first electrode or the second electrode has been oxidized to form an interfacial layer; a thin film comprising crystalline material disposed between the first electrode and the second electrode, the crystalline material comprising hafnium oxide and zirconium oxide, wherein the crystalline material exhibits ferroelectric behavior as deposited; and a voltage source connected to the first electrode or the second electrode.

In an aspect of the first main aspect, the first electrode and the second electrode are independently selected from TIN, W, Ni, Ru, Pt, and Al. In a further aspect of the first main aspect. the first electrode and the second electrode are independently selected from TiN and W. In a further aspect of the first main aspect, the ferroelectric tunnel junction is capable of switching between 4 distinct resistive states. In a further aspect of the first main aspect, the resistance states are stable for at least 103 seconds. In a further aspect of the first main aspect, the FTJ has a memory window of between about 1.5× and about 10× in the DC domain. In a further aspect of the first main aspect, the FTJ has a memory window of between about 2× and about 5×. In a further aspect of the first main aspect, the FTJ is capable of exhibiting ferroelectric activity. In a further aspect of the first main aspect, the first electrode comprises tungsten and the second electrode comprises titanium nitride. In a further aspect of the first main aspect, less than 50% of the total volume of the crystalline material constitutes a non-ferroelectric phase component. In a further aspect of the first main aspect, less than 40% of the total volume of the crystalline material constitutes a non-ferroelectric phase component. In a further aspect of the first main aspect, less than 40% of the total volume of the crystalline material constitutes a monoclinic phase component. In a further aspect of the first main aspect, less than 50% of the total volume of the crystalline material constitutes a monoclinic phase component. In a further aspect of the first main aspect, (i) greater than 50% of the total volume of the crystalline material is in a ferroelectric phase; (ii) less than 50% of the total volume of the crystalline material constitutes a non-ferroelectric phase component; and (iii) less than 25% of the total volume of the crystalline material constitutes a monoclinic phase component. In a further aspect of the first main aspect, a hafnium oxide to zirconium oxide ratio is between approximately 1:3 and approximately 3:1. In a further aspect of the first main aspect, the crystalline material has a carbon content below approximately 6 atomic percent. In a further aspect of the first main aspect, the crystalline material is derived from one or more metallocene precursor having Formula I:

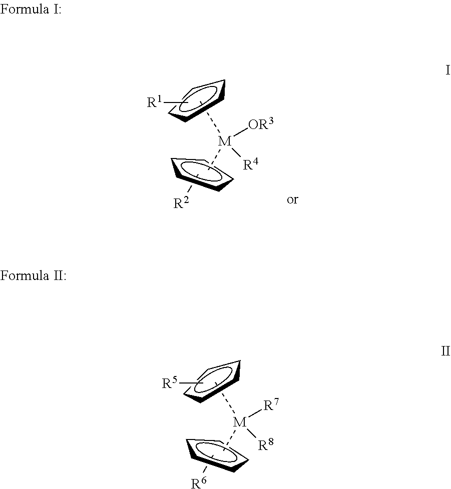

wherein (i) M is selected from Zr and Hf and (ii) R¹, R², R³, R⁴, R⁵, R⁶, R⁷ and R⁸ are each independently selected from a C₁-C₆ linear alkyl, a C₁-C₆ branched alkyl, a C₁-C₆ halogenated linear alkyl and a C₁-C₆ halogenated branched alkyl. In a further aspect of the first main aspect, the crystalline material is derived from one or more metallocene precursor having

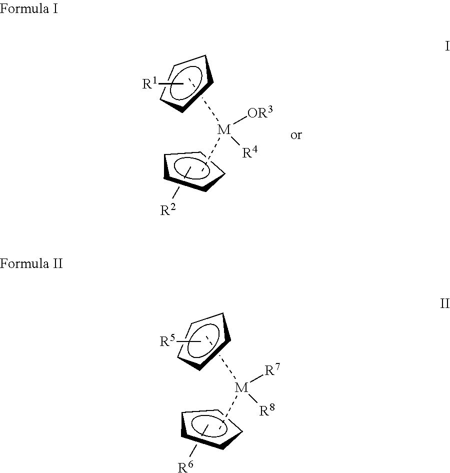

wherein (i) M is selected from Zr and Hf and (ii) R¹, R², R³, R⁴, R⁵, R⁶, R⁷ and R⁸ are each independently a C₁-C₆ linear alkyl. In a further aspect of the first main aspect, the crystalline material is derived from one or more metallocene precursor having

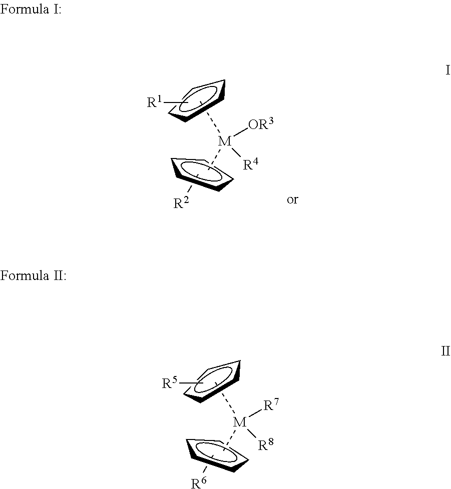

wherein (i) M is selected from Zr and Hf and (ii) R¹, R², R³, R⁴, R⁵, R⁶, R⁷ and R⁸ are each a methyl group. In a further aspect of the first main aspect, there is hysteresis and remanent polarization in a polarization-electric field measurement. In a further aspect of the first main aspect, the film has a thickness of approximately 0.2 nm to approximately 10 nm. In a further aspect of the first main aspect, the film has a thickness of approximately 0.2 nm to approximately 5 nm. In a further aspect of the first main aspect, the film has a remanent polarization (Pr) of greater than 8 μC/cm² or a total loop opening of greater than 16 μC/cm².

In a second main aspect, a method of creating a ferroelectric tunnel junction comprising: (i) providing a substrate; (ii) depositing a first electrode onto the substrate; (iii) depositing a ferroelectric layer onto the first electrode at a deposition temperature, the step of depositing the ferroelectric layer comprising: (a) exposing the first electrode to a first precursor that does not decompose at the deposition temperature; (b) exposing the substrate to a first reaction gas; (c) exposing the substrate to a second precursor that does not decompose at the deposition temperature; and (d) exposing the substrate to a second reaction gas, wherein one of the first precursor and the second precursor comprises zirconium and the other of the first precursor and the second precursor comprises hafnium; and (iv) depositing a second electrode onto the ferroelectric layer.

In a further aspect of the second main aspect, a step of creating an interfacial layer by oxidizing the first electrode is conducted prior to step (iii). In a further aspect of the second main aspect, the first reaction gas and the second reaction gas are each independently a gas containing one or more of oxygen, water, hydrogen peroxide and nitrous oxide. In a further aspect of the second main aspect, the first reaction gas and the second reaction gas are each independently a gas containing oxygen, a gas containing ozone, or a gas containing water. In a further aspect of the second main aspect, an annealing step is conducted at a temperature greater than about 350 degrees Celsius. In a further aspect of the second main aspect, no process steps take place at a temperature greater than about 400 degrees Celsius. In a further aspect of the second main aspect, no interfacial layer is deposited between the ferroelectric layer and the first electrode or between the ferroelectric layer and the second electrode. In a further aspect of the second main aspect, the first gas or the second gas comprises ozone delivered a volumetric fraction of between about 2% and about 50%. In a further aspect of the second main aspect, further comprising an ozone pulsing step prior to depositing the second electrode. In a further aspect of the second main aspect, the ozone pulsing step delivers a gas stream comprising between about 2% and about 50% of ozone by volume. In a further aspect of the second main aspect, the deposited crystalline material exhibits remanent polarization without additional thermal processing. In a further aspect of the second main aspect, the deposited crystalline material has a remanent polarization (Pr) of greater than 8 μC/cm² or a total loop opening of greater than 16 μC/cm². In a further aspect of the second main aspect, the first electrode or the second electrode comprises TiN and the interfacial layer comprises TiOₓN_{y}, wherein x and y are integers. In a further aspect of the second main aspect, the first electrode comprises tungsten and the second electrode comprise titanium nitride. In a further aspect of the second main aspect, further comprising at least one purging step. In a further aspect of the second main aspect, the first reaction gas and the second reaction gas are different gases. In a further aspect of the second main aspect, the first precursor and the second precursor are each independently a precursor having

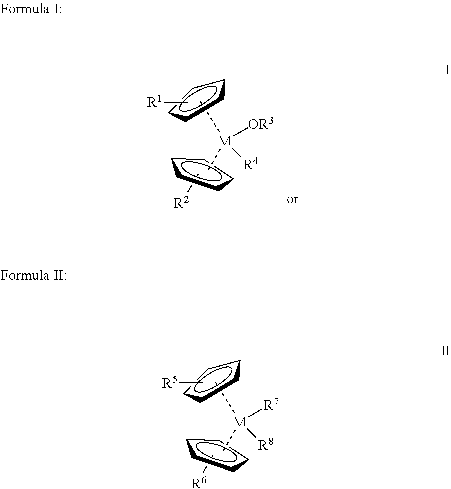

wherein (i) M is selected from Zr and Hf and (ii) R¹, R², R³, R⁴, R⁵, R⁶, R⁷ and R⁸ are each independently selected from a C₁-C₆ linear alkyl, a C₁-C₆ branched alkyl, a C₁-C₆ halogenated linear alkyl and a C₁-C₆ halogenated branched alkyl.

In a further aspect of the second main aspect, the first precursor and the second precursor are each independently a precursor having

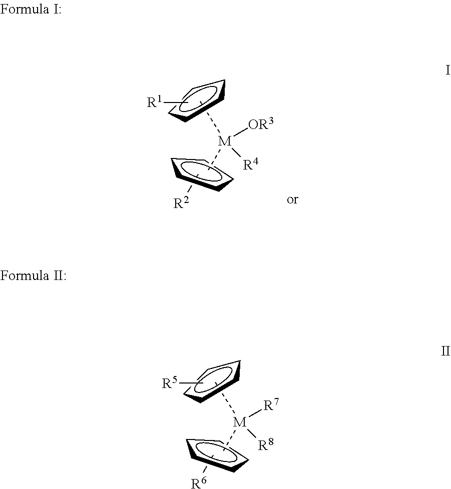

wherein (i) M is selected from Zr and Hf and (ii) R¹, R², R³, R⁴, R⁵, R⁶, R⁷ and R⁸ are each independently a C₁-C₆ linear alkyl.

In a further aspect of the second main aspect, the first precursor and the second precursor are each independently a precursor having

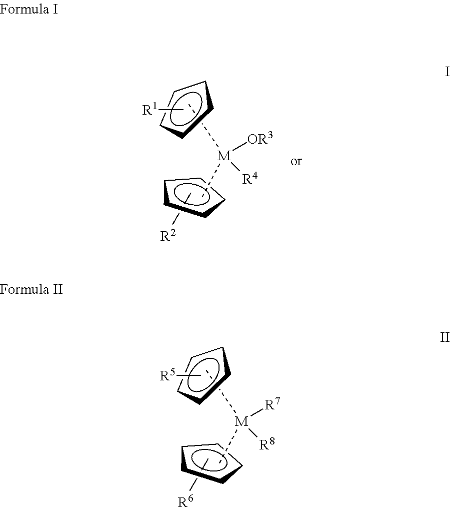

wherein (i) M is selected from Zr and Hf and (ii) R¹, R², R³, R⁴, R⁵, R⁶, R⁷ and R⁸ are each a methyl group.

In a further aspect of the second main aspect, the method comprises an ALD process. In a further aspect of the second main aspect, the method comprises a CVD process. In a further aspect of the second main aspect, the deposition temperature is between approximately 200 degrees Celsius and below approximately 400 degrees Celsius. In a further aspect of the second main aspect, the deposition temperature is between approximately 265 degrees Celsius and below approximately 390 degrees Celsius. In a further aspect of the second main aspect, the deposition temperature is between approximately 280 to approximately 380 degrees Celsius. In a further aspect of the second main aspect, the deposition temperature is below approximately 30 degrees Celsius. In a further aspect of the second main aspect, the substrate comprises silicon, germanium, III-V materials, transition metal dichalcogenides, titanium nitride, titanium, tantalum, tantalum nitride, tungsten, platinum, rhodium, molybdenum, cobalt, ruthenium, palladium, or mixtures thereof, or dielectrics like silicon oxide, silicon nitride, aluminum oxide, titanium oxide. In a further aspect of the second main aspect, the deposited crystalline material has a thickness of approximately 0.2 nm and approximately 20 nm.

In a third main aspect, a method of creating a ferroelectric tunnel junction comprises: (i) providing a substrate; (ii) depositing a first electrode onto the substrate; (iii) pulsing a plasma comprising oxygen and ozone to oxidize a portion of the bottom electrode to form an interfacial layer; (iv) depositing a ferroelectric layer onto the first electrode at a deposition temperature, the step of depositing the ferroelectric layer comprising: (a) exposing the first electrode to a first precursor that does not decompose at the deposition temperature; (b) exposing the substrate to a first reaction gas; (c) exposing the substrate to a second precursor that does not decompose at the deposition temperature; and (d) exposing the substrate to a second reaction gas, wherein one of the first precursor and the second precursor comprises zirconium and the other of the first precursor and the second precursor comprises hafnium; and (v) depositing a second electrode onto the ferroelectric layer.

In an aspect of the third main aspect, the first reaction gas and the second reaction gas are each independently a gas containing one or more of oxygen, water, hydrogen peroxide and nitrous oxide. In a further aspect of the third main aspect, the first reaction gas and the second reaction gas are each independently a gas containing oxygen, a gas containing ozone, or a gas containing water. In a further aspect of the third main aspect, an annealing step is conducted at a temperature greater than or equal to about 350 degrees Celsius. In a further aspect of the third main aspect, no process steps take place at a temperature greater than about 400 degrees Celsius. In a further aspect of the third main aspect, no interfacial layer is deposited between the ferroelectric layer and the first electrode or between the ferroelectric layer and the second electrode. In a further aspect of the third main aspect, the first gas or the second gas comprises ozone delivered a volumetric fraction of between about 2% and about 50%. In a further aspect of the third main aspect. the method further comprises an ozone pulsing step prior to depositing the second electrode. In a further aspect of the third main aspect, the ozone pulsing step delivers a gas stream comprising between about 2% and about 50% of ozone by volume. In a further aspect of the third main aspect, the deposited crystalline material exhibits remanent polarization without additional thermal processing. In a further aspect of the third main aspect, the deposited crystalline material has a remanent polarization (Pr) of greater than 8 μC/cm² or a total loop opening of greater than 16 μC/cm². In a further aspect of the third main aspect, the first electrode comprises TiN and the interfacial layer comprises TiOₓN_{y}, wherein x and y are integers. In a further aspect of the third main aspect, the first electrode comprises Tungsten (W) and the interfacial layer comprises WOₓ, wherein x is an integer. In a further aspect of the third main aspect, the first electrode comprises Ruthenium (Ru) and the interfacial layer comprises RuOₓ, wherein x is an integer. In a further aspect of the third main aspect, the first electrode comprises tungsten and the second electrode comprises titanium nitride. In a further aspect of the third main aspect, the annealing step is conducted at a temperature lower than or equal to about 400 degrees Celsius.

In a further aspect of the first, second, or third main aspect, the film comprises HfₓZr₁₋ₓO₂ or HfO₂ doped with La, Y, Gd, or Sr. In a further aspect of the first, second, or third main aspect, a crossbar memory array comprises the ferroelectric tunnel junction of any of claims 1-[0140]23 or the ferroelectric tunnel junction created by the method of any of claims [0140]24-[0140]66 comprising a memory unit cell. In a further aspect of the first, second, or third main aspect, a neuromorphic computing chip comprising the ferroelectric tunnel junction of any of claims 1-[0140]23, wherein the ferroelectric tunnel junction is a synaptic device. In a further aspect of the first, second, or third main aspect, the ferroelectric tunnel junction has a critical dimension of about 300 nm or less.

In another aspect, the advanced metallocene precursor is one or more of the precursors disclosed and/or claimed in U.S. Pat. No. 8,568,530 the contents of which is incorporated herein in its entirety.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates an ALD windows for different precursors of Hf and Zr oxide deposition;

FIGS. 2A-2D illustrate alternative embodiments of a ferroelectric tunnel junction disclosed herein;

FIG. 3A illustrates an embodiment of a process for depositing an example of the inherently ferroelectric materials disclosed herein on a substrate;

FIG. 3B illustrates an embodiment of a layer comprising inherently ferroelectric materials on a bottom electrode (TiN) on a substrate;

FIG. 3C illustrates another process for depositing inherently ferroelectric materials on a stack;

FIG. 4A illustrates a schematic of a metal-ferroelectric-metal (MFM) capacitor used to measure thin HZO film properties;

FIG. 4B illustrates a schematic of a sub-μm scaled FTJ device on an in-house test vehicle;

FIG. 5A illustrates a cross-sectional HR-TEM image of a HZO film deposited on a 50 nm W electrode and capped with a 50 nm TiN electrode;

FIG. 5B illustrates an electron energy loss (EELS) line scan across the device stack illustrated in FIG. 5A;

FIG. 5C illustrates an XRD pattern of the HZO thin film after post metal anneal;

FIG. 6A illustrates polarization versus electric field before and after wake-up stress;

FIG. 6B illustrates current-voltage DC sweeps of the scaled device before and after wake-up stress;

FIG. 7A illustrates resistance versus programming voltage for the scaled device;

FIG. 7B illustrates resistance versus programming voltage for the scaled device for a different write pulse width;

FIG. 7C illustrates resistance versus programming voltage for 4 scaled devices;

FIG. 7D illustrates stability of 4 resistance levels for the scaled device;

FIGS. 8A-8F illustrate conductance over number of pulses illustrating good linearity for the 4% ozone embodiment of the scaled device;

FIG. 9 illustrate resistance versus voltage after different post metal anneal conditions;

FIGS. 10A and 10B illustrate multi-level states retention over time measured at room temperature; and

FIG. 11 illustrates cycling endurance performance.

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including.” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., +10%, +5%), whichever is greater.

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B.” “A or B.” “A” and “B.”

The terms “substituent,” “radical,” “group” and “moiety” may be used interchangeably.

As used herein, the terms “metal-containing complex” (or more simply, “complex”) and “precursor” are used interchangeably and refer to a metal-containing molecule or compound which can be used to prepare a metal-containing film by a deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal nitride film, metal silicide film, a metal carbide film and the like.

As used herein, the terms “elemental metal,” “elemental metal film” and “pure metal film” are used interchangeably and refer to a film which consists of, or consists essentially of, pure metal. For example, an elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. However, a film comprising an elemental metal is distinguished from binary films including a metal and a non-metal (e.g., C, N, O) and ternary films including a metal and two non-metals (e.g., C, N, O), though, a film comprising elemental metal may include some amount of impurities. Unless context dictates otherwise, the term “metal film” shall be interpreted to mean an elemental metal film.

As used herein, the terms “deposition process” and “thermally depositing” are used to refer to any type of deposition technique, including but not limited to, CVD and ALD. In various embodiments, CVD may take the form of conventional (i.e., continuous flow) CVD, liquid injection CVD, plasma-enhanced CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al., J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n-or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. The substituents may be any of the acyclic alkyl groups described herein. As mentioned herein the cyclic alkyl groups may have any of the acyclic alkyl groups as substituent. These alkyl moieties may be substituted or unsubstituted.

“Halogenated alkyl” refers to a linear, cyclic, or branched saturated alkyl group as defined above in which one or more of the hydrogens has been replaced by a halogen (e.g., F, Cl, Br, and I). Thus, for example, a fluorinated alkyl (a.k.a. “fluoroalkyl”) refers to a linear, cyclic or branched saturated alkyl group as defined above in which one or more of the hydrogens has been replaced by fluorine (e.g., trifluoromethyl, pefluoroethyl, 2,2,2-trifluoroethyl, prefluoroisopropyl, perfluorocyclohexyl and the like). Such haloalkyl moieties (e.g., fluoroalkyl moieties), if not perhalogenated/multihalogenated, may be unsubstituted or further substituted.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

I. Ferroelectric Tunnel Junction with Multilevel Switching

Ferroelectric Tunnel Junctions (FTJ) recently have been studied as one of the best candidates as memristor or artificial synapse thanks to its unique analog-type programming fundamental for neuromorphic computing applications. Use of ALD HZO film deposited at high T with specific precursors (HfD-04 and ZrD-04) sandwiched between a TiN electrode and a W electrode, and specific Post Metal Anneal (PMA) allows for multilevel programming up to 4 levels with retention on a par with current state of the art for FTJ that generally uses bilayer stack with higher complexity. This disclosure paves the way for future implementation of FTJ in neuromorphic computing chips.

The instant disclosure demonstrates a new technique to introduce asymmetry between a top electrode and a bottom electrode. This is facilitated by the high temperature (>300C) atomic layer deposition (ALD) of Hafnium Zirconium Oxide (HZO) using the alternate cycling of the Hf and Zr precursors (HfD-04 and ZrD-04) with ozone pulsing for oxidation in between.

This deposition builds the FTJ stack in such a way that it can be made without any interfacial dielectric layer and can switch between high memory window (2×-10×). In the state-of-the-art system of fabricating ferroelectric memory devices, typically FE materials are deposited using lower temperature ALD that makes the film amorphous as-deposited and hence non-FE, followed by a high temperature annealing (>500C) to crystallize the film and activate the FE properties of the film. For an FTJ with an interfacial layer an additional processing step is needed to deposit the interfacial material. The instant process integration and stack allow for as-deposited FE film because of the precursor's ability to handle high temperature (>300C). Additionally, the process inherently oxidizes the bottom electrode (due to its high temperature and highly reactive ozone process) to create interfacial metal oxide that introduces the asymmetry required for FTJ operation. Further annealing at higher than the deposition temperature can be introduced to improve the FE memory window and reliability metric like retention and endurance.

Additionally, the optimization of HZO film, the FTJ stack demonstrate good tunability of tunneling electroresistance (TER) and this makes it programmable up to 4 distinct levels with each level having a good memory retention up to a least 10-3 seconds. The implication of 4 distinct memory levels allows storing of up to 2 bits of information in one single FTJ cell as opposed to 1 bit per cell for the binary switching FTJ. Proper choice of ALD deposition temperature, ozone dilution and post-metal anneal conditions are fundamental to obtain the desired orthorhombic phase needed for ferroelectric multi-domain switching that is essential for multi-level switching in FTJ.

The demonstrated FTJ cell besides storing multi-bit digital information can also be used as an analog memory that can store its resistance values that are gradually tunable within a certain range. The instant FTJ shows >2× dynamic range in the gradual switching of resistance in FTJ that has not been demonstrated to this date.

The instant disclosure for the first time shows BEOL compatible process with a Hafnium Zirconium Oxide (HZO) switching layer sandwiched between asymmetric TiN and W electrodes with multilevel programming up to 4 states and good retention of these states for at least 103 s. During HZO deposition an oxidized interfacial layer (TiOₓN_{y}) is created by oxidizing the TIN bottom electrode interface. An advantage of this step is that is occurs concomitantly in the deposition process and an additional process step is not needed. In a further embodiment, the first electrode comprises W and the oxidized interfacial layer comprises WOₓ. In another embodiment, the first electrode comprise Ru and the oxidized interfacial layer comprises RuOₓ.

The inherently ferroelectric thin film materials and the methods of their use, which address the forgoing issues, are disclosed here and in U.S. Provisional Patent Application No. 63/040,097 filed on Jun. 17, 2020 (Attorney Docket No. P20-094 US-PRO), and PCT Application No. PCT/EP2021/066028 filed Jun. 15, 2021 (P20-094 WO-PCT). These applications are incorporated by reference in their entireties. In doing so, the materials and methods described herein reduce processing time making them especially amenable to the demands of current manufacturing procedures. The disclosure involves the FTJs having 9 or more distinct resistance levels. Those skilled in the art can readily appreciate the potential for subsequent optimization of interfaces, electrodes, and thermal processing conditions after deposition of these materials.

### II. Inherently Ferroelectric Materials

As set forth above, the disclosed and claimed subject matter relates to crystalline ferroelectric thin film materials that include a mixture of hafnium oxide and zirconium oxide having a substantial (i.e., approximately 40% or more) portion of the material in a ferroelectric phase and methods for preparing and depositing these materials. In a further aspect, the ferroelectric materials have a majority volume fraction of a ferroelectric phase. Significantly, these materials exhibit ferroelectric properties without the need for further processing, such as a subsequent capping step or annealing step. To be ferroelectric, the produced materials have one or more of (i) remanent polarization or (ii) a polarization field curve with hysteresis and a loop opening.

In order to be ferroelectric, the material must have an arrangement of atoms that can support ferroelectricity in some fraction of the film. It is preferable that a substantial portion of the volume of the film have an arrangement of atoms that can support ferroelectricity. It is understood that for thin films, doped materials, and some laminated materials, the phase distribution in the material may not be easily determined by x-ray diffraction. In this case, any other suitable technique for establishing the phase of the film, such as Raman spectroscopy, infrared spectroscopy, x-ray absorption spectroscopy, transmission electron microscopy, or combinations thereof, may be used to determine the phase distribution. For example, https://onlinelibrary.wiley.com/doj/full/10.1002/pssb.201900285 describes a technique for ascertaining the phase of a film to within approximately 10%.

The material can be comprised of any suitable molar ratio of hafnium oxide and zirconium oxide-ratios between 1:3 and 3:1 are preferred. The thickness of the ferroelectric material is any thickness that is suitable for the given application; the material can be made thicker to increase the remanent polarization or reduce the electrical leakage current through the thickness of the material. The material can be made thinner because of geometric constraints or to increase the capacitance of the film.

The preferred range of thicknesses for this ferroelectric film is approximately 0.2 nm to approximately 20 nm and is more preferably approximately 0.2 nm to 10 nm. It is also preferable that the materials form films having a thickness of approximately 10 nm and less. In some embodiments it is preferable that the materials form films having a thickness of approximately 5 nm and less.

As discussed above, however, preferred and/or desired thicknesses will change depending on specific application. Thus, as noted previously, in some embodiments the materials exhibit ferroelectric properties as thin films of approximately 20 nm or less. In a further aspect the materials exhibit ferroelectric properties as thin films of approximately 15 nm or less. In a further aspect, the materials exhibit ferroelectric properties as thin films of approximately 10 nm or less. In a further aspect, the materials exhibit ferroelectric properties as thin films of approximately 5 nm or less. In a further aspect, the materials exhibit ferroelectric properties as thin films of approximately 3 nm or less. In a further aspect, the materials exhibit ferroelectric properties as thin films of approximately 1 nm or less. In a further aspect, the materials exhibit ferroelectric properties as thin films of approximately 0.5 nm or less. In a further aspect, the materials exhibit ferroelectric properties as thin films of approximately 0.2 nm or less. In a further aspect, the materials exhibit ferroelectric properties as thin films of between approximately 0.2 nm to approximately 20 nm. In a further aspect, the materials exhibit ferroelectric properties as thin films of between approximately 0.2 nm to approximately 15 nm. In a further aspect, the materials exhibit ferroelectric properties as thin films of between approximately 0.2 nm to approximately 10 nm. In a further aspect, the materials exhibit ferroelectric properties as thin films of between approximately 0.2 nm to approximately 5 nm. In a further aspect, the materials exhibit ferroelectric properties as thin films of between approximately 0.2 nm to approximately 3 nm. In a further aspect, the materials exhibit ferroelectric properties as thin films of between approximately 0.2 nm to approximately 1 nm. In a further aspect, the materials exhibit ferroelectric properties as thin films of between approximately 0.2 nm to approximately 1 nm.

In the disclosed and claimed materials, a substantial portion constituting approximately 40% or more of the crystalline material is in a ferroelectric phase, thus the total non-ferroelectric atomic arrangement components are less than approximately 60% of the total volume of the material. In another embodiment, the total non-ferroelectric atomic arrangement components are less than approximately 50% of the total volume of the material. In another embodiment, the total non-ferroelectric atomic arrangement components are less than approximately 40% of the total volume of the material. In another embodiment, the total non-ferroelectric atomic arrangement components are less than approximately 30% of the total volume of the material. In another embodiment, the total non-ferroelectric atomic arrangement components are less than approximately 25% of the total volume of the material. In another embodiment, the total non-ferroelectric atomic arrangement components are less than approximately 20% of the total volume of the material. In another embodiment, the total non-ferroelectric atomic arrangement components are less than approximately 15% of the total volume of the material. In another embodiment, the total non-ferroelectric atomic arrangement components are less than approximately 10% of the total volume of the material. In another embodiment, the total non-ferroelectric atomic arrangement components are less than approximately 5% of the total volume of the material.

Moreover, in the disclosed and claimed materials less than approximately 60% of the of the total volume of the material constitutes a non-ferroelectric monoclinic phase component. Thus, in one embodiment of the disclosed and claimed materials, a monoclinic phase component is less than approximately 50% of the total volume of the material. In another embodiment, a monoclinic phase component is less than approximately 40% of the total volume of the material. In another embodiment, a monoclinic phase component is less than approximately 30% of the total volume of the material. In another embodiment, a monoclinic phase component is less than approximately 25% of the total volume of the material. In another embodiment, a monoclinic phase component is less than approximately 20% of the total volume of the material. In another embodiment, a monoclinic phase component is less than approximately 15% of the total volume of the material. In another embodiment, a monoclinic phase component is less than approximately 10% of the total volume of the material. In another embodiment, a monoclinic phase component is less than approximately 5% of the total volume of the material.

In the disclosed and claimed subject matter, the preferred carbon content of the material is below approximately 6 atomic percent as measured by a suitable technique, such as x-ray photo electron spectroscopy. In a further aspect, the carbon content below approximately 5 atomic percent. In a further aspect, the carbon content below approximately 4 atomic percent. In a further aspect, the carbon content below approximately 3 atomic percent. In a further aspect, the carbon content below approximately 2 atomic percent. In a further aspect, the carbon content below approximately 1 atomic percent. In a further aspect, the carbon content is between approximately 1 atomic percent and approximately 6 percent. In a further aspect, the carbon content is between approximately 1 atomic percent and approximately 5 percent. In a further aspect, the carbon content is between approximately 1 atomic percent and approximately 4 percent. In a further aspect, the carbon content is between approximately 1 atomic percent and approximately 3 percent. In a further aspect, the carbon content is between approximately 1 atomic percent and approximately 2 percent.

The inherently ferroelectric materials are derived from metallocene precursor from advanced metallocene precursors having the Formula I (“(R¹-Cp)(R²-Cp)-M-(OR³) (R⁴)” where Cp is a cyclopentadienyl group) and/or Formula II (“(R⁵-Cp)(R⁶-Cp)-M-(R⁷)(R⁸)” where Cp is a cyclopentadienyl group):

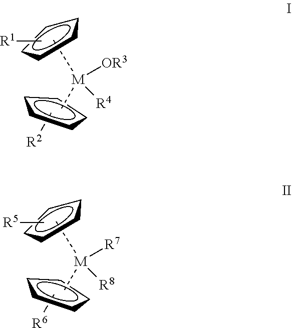

where: M=Zr or Hf; and
R¹, R², R³, R⁴, R⁵, R⁶, R⁷ and R⁸ are each independently selected from a C₁-C₆ linear alkyl, a C₁-C₆ branched alkyl, a C₁-C₆ halogenated linear alkyl and a C₁-C₆ halogenated branched alkyl.

In another aspect, in Formula I each of R¹, R², R³, R⁴, R⁵, R⁶, R⁷ and R⁸ is preferably a C₁-C₆ linear alkyl. In a further aspect, in Formula I each of R¹, R², R³, R⁴, R⁵, R⁶, R⁷ and R⁸ is preferably the same C₁-C₆ linear alkyl. In a further aspect, in Formula I each of R¹, R², R³, R⁴, R⁵. R⁶, R⁷ and R⁸ is preferably a methyl group. In a further aspect, in Formula I each of R¹, R², R³. R⁴, R⁵, R⁶, R⁷ and R⁸ is preferably an ethyl group. In a further aspect, in Formula I each of R¹, R². R⁵ and R⁶ is preferably an ethyl group. In a further aspect, in Formula I each of R³, R⁴, R⁷ and R⁸ is preferably a methyl group. In a further aspect, in Formula I each of R¹, R², R⁵ and R⁶ is preferably an ethyl group and each of R³, R⁴, R⁷ and R⁸ is preferably a methyl group.

In another aspect, in Formula II each of R¹, R², R³, R⁴, R⁵, R⁶, R⁷ and R⁸ is preferably a C₁-C₆ linear alkyl. In a further aspect, in Formula II each of R¹, R², R³, R⁴, R⁵, R⁶, R⁷ and R⁸ is preferably the same C₁-C₆ linear alkyl. In a further aspect, in Formula II each of R¹, R². R³, R⁴, R⁵, R⁶, R⁷ and R⁸ is preferably a methyl group. In a further aspect, in Formula II each of R¹, R², R³, R⁴, R⁵, R⁶, R⁷ and R⁸ is preferably an ethyl group. In a further aspect, in Formula II each of R¹, R², R⁵ and R⁶ is preferably an ethyl group. In a further aspect, in Formula II each of R³, R⁴, R⁷ and R⁸ is preferably a methyl group. In a further aspect, in Formula II each of R¹, R². R⁵ and R⁶ is preferably an ethyl group and each of R³, R⁴, R⁷ and R⁸ is preferably a methyl group.

In another aspect, the advanced metallocene precursor is one or more of (MeCp)₂Zr(OMe)Me. (MeCp)₂Hf(Ome)Me, (MeCp)₂Zr(Me)₂, (MeCp)₂Hf(Me)₂, (EtCp)₂Zr(Ome)Me, (EtCp)₂Hf(Ome)Me, (EtCp)₂Zr(Mc)₂, (EtCp)₂Hf(Me)₂, and combinations thereof.

In another aspect, the advanced metallocene precursor is one or more mixture of (MeCp)₂Zr(Ome)Me and (MeCp)₂Hf(Ome)Me, a mixture of (MeCp)₂Hf(Me)₂ and (MeCp)₂Hf(Me)₂, (EtCp)₂Zr(Ome)Me and (EtCp)₂Hf(Ome)Me and a mixture of (EtCp)₂Hf(Me)₂ and (EtCp)₂Hf(Me)₂.

In another aspect, the advanced metallocene precursor is one or more of the precursors disclosed and/or claimed in U.S. Pat. No. 8,568,530 the contents of which is incorporated herein in its entirety.

### III. Methods for Preparing and Depositing Inherently Ferroelectric Materials

As noted above, in another aspect the disclosed and claimed subject matter is directed to a process for preparing and/or depositing the inherently ferroelectric materials disclosed herein. In this process, the disclosed and claimed inherently ferroelectric materials are prepared by iterative depositions and purges (i) of a metallocene precursor and (ii) a reactant.

### A. Metallocene Precursors

As noted above, the ferroelectric materials are derived from advanced metallocene precursors having the Formula I (“(R¹-Cp) (R²-Cp)-M-(OR³) (R⁴)” where Cp is a cyclopentadienyl group) and/or Formula II (“(R⁵-Cp) (R⁶-Cp)-M-(R⁷) (R⁸)” where Cp is a cyclopentadienyl group):

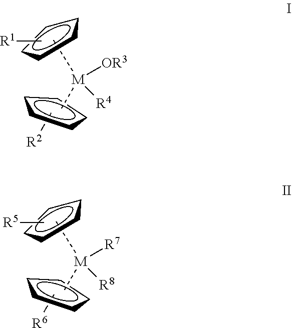

where: M=Zr or Hf; and
R¹, R², R³, R⁴, R⁵, R⁶, R⁷ and R⁸ are each independently selected from a C₁-C₆ linear alkyl, a C₁-C₆ branched alkyl, a C₁-C₆ halogenated linear alkyl and a C₁-C₆ halogenated branched alkyl.

In another aspect, in Formula I each of R¹, R², R³, R⁴, R⁵, R⁶, R⁷ and R⁸ is preferably a C₁-C₆ linear alkyl. In a further aspect, in Formula I each of R¹, R², R³, R⁴, R⁵, R⁶, R⁷ and R⁸ is preferably the same C₁-C₆ linear alkyl. In a further aspect, in Formula I each of R¹, R², R³, R⁴, R⁵, R⁶, R⁷ and R⁸ is preferably a methyl group. In a further aspect, in Formula I each of R¹, R², R³, R⁴, R⁵, R⁶, R⁷ and R⁸ is preferably an ethyl group. In a further aspect, in Formula I each of R¹, R², R⁵ and R⁶ is preferably an ethyl group. In a further aspect, in Formula I each of R³, R⁴, R⁷ and R⁸ is preferably a methyl group. In a further aspect, in Formula I each of R¹, R², R⁵ and R⁶ is preferably an ethyl group and each of R³, R⁴, R⁷ and R⁸ is preferably a methyl group.

In another aspect, in Formula II each of R¹, R², R³, R⁴, R⁵, R⁶, R⁷ and R⁸ is preferably a C₁-C₆ linear alkyl. In a further aspect, in Formula II each of R¹, R², R³, R⁴, R⁵, R⁶, R⁷ and R⁸ is preferably the same C₁-C₆ linear alkyl. In a further aspect, in Formula II each of R¹, R², R³, R⁴, R⁵, R⁶, R⁷ and R⁸ is preferably a methyl group. In a further aspect, in Formula II each of R¹, R², R³, R⁴, R⁵, R⁶, R⁷ and R⁸ is preferably an ethyl group. In a further aspect, in Formula II each of R¹, R², R⁵ and R⁶ is preferably an ethyl group. In a further aspect, in Formula II each of R³, R⁴, R⁷ and R⁸ is preferably a methyl group. In a further aspect, in Formula II each of R¹, R². R⁵ and R⁶ is preferably an ethyl group and each of R³, R⁴, R⁷ and R⁸ is preferably a methyl group.

In another aspect, the advanced metallocene precursor is one or more of (MeCp)₂Zr(Ome)Me, (MeCp)₂Hf(Ome)Me, (MeCp)₂Zr (Mc)₂. (MeCp)₂Hf (Me)₂, (EtCp)₂Zr(Ome)Me, (EtCp)₂Hf(Ome)Me, (EtCp)₂Zr (Mc)₂, (EtCp)₂Hf (Me)₂, and combinations thereof.

In another aspect, the advanced metallocene precursor is one or more mixture of (MeCp)₂Zr(Ome)Me and (MeCp)₂Hf(Ome)Me, a mixture of (MeCp)₂Hf (Me)₂ and (MeCp)₂Hf (Me)₂, (EtCp)₂Zr(Ome)Me and (EtCp)₂Hf(Ome)Me and a mixture of (EtCp)₂Hf (Me)₂ and (EtCp)₂Hf (Mc)₂.

In another aspect, the advanced metallocene precursor is one or more of the precursors disclosed and/or claimed in U.S. Pat. No. 8,568,530 the contents of which is incorporated herein in its entirety.

In general, suitable precursors for preparing the inherently ferroelectric materials are able to be deposited at or near the crystallization temperature of the desired ferroelectric material, typically between approximately 200° C. and approximately 570° C. depending on the composition of the material, substrate, and reactor design, among other factors. A preferred temperature is approximately 300° C. (or generally between approximately 280° C. and approximately 300° C.), and the preferred temperature range is below approximately 450° C. and more preferably below approximately 340° C. However, those skilled in the art should recognize that other temperatures may be possible depending on the specific precursor used and that such precursors also fall within the scope of the disclosed and claimed subject matter. It should further be noted that with certain precursors besides the ones listed here, decomposition of the precursor can occur within the temperature range described. Decomposition products, in particular carbon and organic species, can become incorporated in the deposited hafnium oxide or zirconium oxide material. While this incorporation of carbon may assist with the stabilization of the ferroelectric phase, it may be undesirable for material purity reasons. Thus, as discussed above, the preferred carbon content of the material is below approximately 6 atomic percent.

### B. Reactant

The reactant is a reaction gas containing one or more of oxygen (e.g., ozone, elemental oxygen, molecular oxygen/O₂), water, hydrogen peroxide and nitrous oxide. In one embodiment, ozone is a preferred reactant gas. In another embodiment, water is a preferred reactant gas.

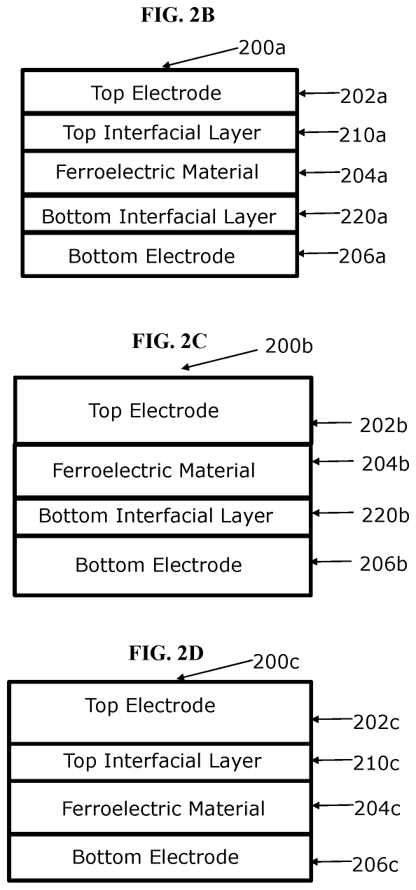

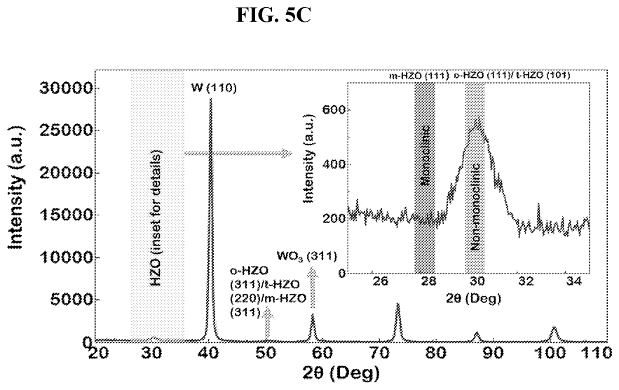

FIGS. 2A-2D illustrate alternative embodiments of a ferroelectric tunnel junction disclosed herein. FIG. 2A shows the FTJ having a top electrode 102, a layer of ferroelectric material 104, and a bottom electrode 106 on a substrate 108. FIG. 2B shows an FTJ embodiment 200a having a top electrode 202a, a top interfacial layer 210a, a layer of ferroelectric material 204a, a bottom interfacial layer 220a, and a bottom electrode 206a on a substrate (not shown). FIG. 2C shows an FTJ embodiment 200b having a top electrode 202b, a layer of ferroelectric material 204b, a bottom interfacial layer 220b, and a bottom electrode 206b on a substrate (not shown). FIG. 2D shows an FTJ embodiment 200c having a top electrode 202c, a top interfacial layer 210c, a layer of ferroelectric material 204c, and a bottom electrode 206c on a substrate (not shown). In the embodiment illustrated in FIG. 5A, the top electrode comprises TiN, the layer of ferroelectric material comprises hafnium and zirconium oxide (HZO), the bottom interfacial layer comprises tungsten oxide (WOₓ), and the bottom layer comprises tungsten.

### C. Process Steps

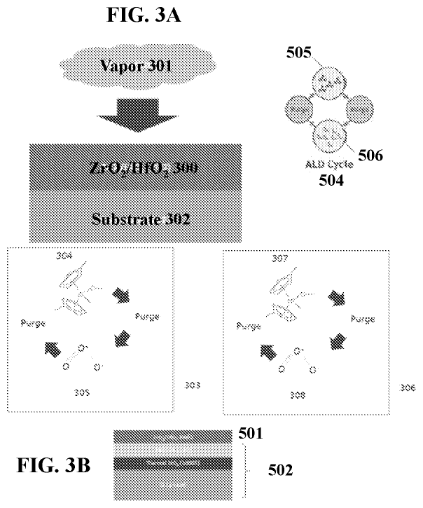

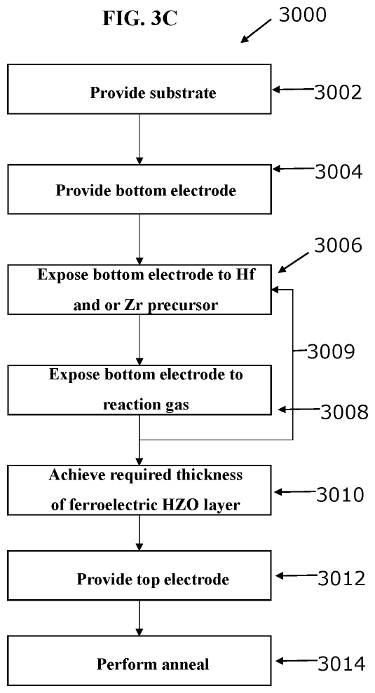

FIG. 3A illustrates an embodiment of a process for preparing and depositing the inherently ferroelectric materials descried herein. As illustrated, substrate 502 undergoes an ALD cycle 504 in which substrate 502 is exposed to vapor 201 to form and deposit an inherently ferroelectric material as thin film layer 300. Layer 300 was formed without further thermal processing or capping and exhibited ferroelectric properties as such (i.e., as deposited). Those skilled in the art recognize, of course, that layer 300 could be subsequently annealed and/or capped as desired but that doing so was not necessary to observe ferroelectric behavior of the layer as deposited. For example, energy can subsequently be applied to the material by, but not limited to, thermal, plasma, pulsed plasma, helicon plasma, high density plasma, inductively coupled plasma, X-ray, c-beam, photon, remote plasma methods, and combinations thereof.

The constituents of vapor 301 change during ALD cycle 504. In particular, substrate 502 is alternatingly exposed to metallocene precursor 505 followed by a purge and then exposed to reactant 506 followed by another purge. This process continues until a desired thickness for layer 300 is obtained. Although ALD is a preferred vapor deposition technique, any suitable vapor phase deposition technique can be utilized, such as CVD or pulsed CVD. Thus, for example, in FIG. 3A ALD cycle 504 could be replaced by a CVD process in which metallocene precursor 505 and reactant 506 are provided as a mixture in vapor 201 and provided simultaneously to substrate 502.

An appropriate molar ratio of hafnium oxide to zirconium oxide can be created by several methods, including introducing a hafnium-containing precursor during a fraction of these cycles, and a zirconium-containing precursor during other cycles. The cycles could alternate, be grouped together, or arranged in any other suitable sequence to produce the overall desired molar ratio, as both intimately blended materials and nanolaminated materials have been shown to have desirable ferroelectric properties. It should be noted that other elements may be added into the hafnium oxide-zirconium oxide material by adding appropriate precursors either along with the hafnium and zirconium precursors, or in separate cycles.

Substrate 502 on which the inherently ferroelectric material is formed as layer 300 can include any suitable material, including semiconducting materials like silicon, germanium, III-V materials, transition metal dichalcogenides, and mixtures thereof, metals and conductive ceramics like titanium nitride, titanium, tantalum, tantalum nitride, tungsten, platinum, rhodium, molybdenum, cobalt, ruthenium, palladium, or mixtures thereof, or dielectrics like silicon oxide, silicon nitride, aluminum oxide, titanium oxide, other ferroelectric materials, including compositions of hafnium oxide and zirconium oxide, magnetic materials, and mixtures or stacks thereof.

Optionally, substrate 302 can be patterned or textured, as appropriate, with any suitable topography, including flat surfaces, trenches, vias, or nanostructured surfaces. This list represents typical substrates that may be useful in ferroelectric applications, but should not be considered limiting, as many other suitable compositions and surface patterns would be obvious to those skilled in the art. In this regard, it is known that the substrate can have some influence on the atomic arrangement and phase of the film formed thereon, including affecting the crystalline orientation and crystallization temperature of the film. Regardless of the particular substrate and the extent of this effect, the inherently ferroelectric materials described herein and deposited on such substrates nevertheless have a substantial fraction of their volume in the ferroelectric phase as deposited.

FIG. 3A illustrates another embodiment of a process for preparing and depositing the inherently ferroelectric materials descried herein. In this embodiment, a mixed hafnium oxide and zirconium oxide inherently ferroelectric material is prepared and deposited as layer 501 with a thickness of approximately 8.4 nm is on a stacked substrate 302 of PVD TiN (which is in direct contact with the ferroelectric material), a thermally grown SiO₂ layer and a Si wafer. Layer 501 was formed without further thermal processing or capping. In this embodiment, the molar ratio of hafnium oxide to zirconium oxide is approximately 1:1, with a margin of error of approximately 10%. The ferroelectric material is prepared and deposited as layer 501 from the vapor by ALD by alternating First Cycle 303 (which includes the steps of (i) pulsing (MeCp)₂Zr(Ome)Me 304, (ii) purging, (iii) pulsing ozone 305 and (iv) purging) and Second Cycle 306 (which includes the steps of (i) pulsing (MeCp)₂Hf(Ome)Me 307, (ii) purging, (iii) pulsing ozone 308 and (iv) purging).

Those skilled in the art will recognize that other precursors, such as (MeCp)₂HfMe₂ and (MeCp)₂ZrMe₂ and other reactants, such as water, hydrogen peroxide or oxygen plasma, may also or alternatively be used. Those skilled in the art will further recognize that the pulsing and purging times can each respectively vary depending on equipment. In one embodiment, pulses last from approximately 2 to approximately 3 seconds followed by a purge of approximately 10 seconds. In another embodiment, pulses last from approximately 10 to approximately 15 seconds followed by a purge of approximately 30 seconds to approximately 60 seconds. In another embodiment, the order in which the precursors are deposited can be reversed.

FIG. 3B illustrates an embodiment of a layer 501 comprising inherently ferroelectric ZrO₂ HfO₂ on a stack 502 comprising a bottom electrode (TiN), thermal SiO₂, and p-type Si.

FIG. 3C illustrates a process of providing a substrate 3002, providing a bottom electrode 3004, exposing the bottom electrode to Hf and or Zr precursor 3006, exposing the bottom electrode to reaction gas 3008, repeating 3009 steps 3006 and 3008 to achieve the required thickness 3010, providing a top electrode 3012, and performing an annealing step 3014. In the preferred embodiment, all steps 3002 to 3014 are performed at a temperature of less than 400 degrees Celsius.

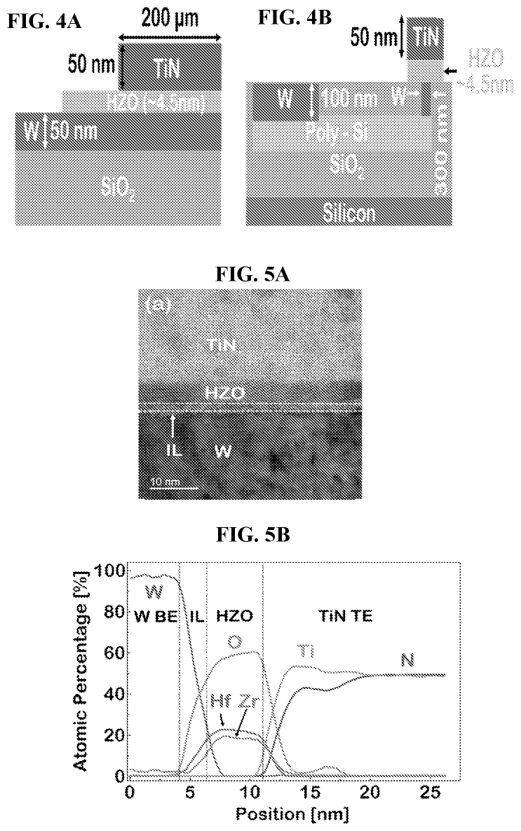

FIG. 4A illustrates a schematic of a metal-ferroelectric-metal (MFM) capacitor used to measure thin HZO film properties. FIG. 4B illustrates a schematic of a sub-μm scaled FTJ device on an in-house test vehicle. To confirm the ferroelectricity switching of the thin HZO film, large area metal-ferroelectric-metal (MFM) capacitors (FIG. 4A) were fabricated. Then, to integrate the HZO thin film into FTJ stack and confirm effective and reliable memory switching a sub-μm scaled FTJ was formed on an in-house test vehicle with different embedded poly-Si in series resistors. FIG. 4B shows the schematic of the FTJ device after integration. In this work, 20 kΩ series resistor has been used during electrical characterization of FTJ devices to avoid chances of possible breakdown of the dielectric. Please note that same device stack has been used in MFM capacitors and FTJ devices to have consistency across different devices.

For simple large (˜200 μm diameter) MFM stack fabrication, initially we deposit thick W layer (50 nm) as the bottom electrode (BE) using a PVD process. Then, the HZO film (˜4.5 nm) is deposited by ALD. This is followed by the top electrode (TE) deposition (50 nm TiN deposited by PVD), 2 min PMA at 400° C. in N2, patterning of the TE and SF6/Ar etch. These simple large MFM stacks are used for measuring FE polarization characteristics of the film, since measuring polarization requires the measurement of displacement current which, being close to the instrument noise floor for most common high-k dielectrics, is difficult for smaller area (<1 μm²) devices. On the other hand, the leakage current in larger devices also is high enough to case the requirement of sensitive measurement. To integrate the sub-μm FTJ device, thin HZO FE film has been chosen to increase current density that make it possible to perform pulsed write and read operations at low voltages. Films were deposited on an in-house test vehicle, with a 300 nm diameter W plug buried in SiO₂. The process starts with ALD HZO deposition (˜4.5 nm) followed by the 50 nm TiN TE deposition by PVD, 2 min PMA at 400° C. in N2, patterning of TE and a final SF6/Ar etch to define the TE region, similarly to the MFM process flow.

FIG. 5C illustrates the grazing-incidence XRD pattern for the inherently ferroelectric material (thin HZO after 2 min PMA at 400C in N2. Both W and WO₃ peaks are visible. The inset portion of FIG. 5C shows high non-monoclinic crystalline phase present for HZO and no monoclinic peak. As shown in FIG. 5C, the crystalline peaks of the material constituting layer 501 show a low monoclinic component and a high non-monoclinic component. By fitting the peaks and using the peak areas with the technique described by McBriarty et al., https://onlinelibrary.wiley.com/doi/full/10.1002/pssb.201900285, the calculated monoclinic fraction of the volume of the of the material constituting layer 501 is less than 25%, which is the preferred maximum volume fraction of monoclinic, non-ferroelectric material. We can observe very sharp metallic W peak from the BE. However, besides the metallic W peak, we observed prominent peaks of WOₓ confirming the findings of the EELS spectra. Closer inspection (inset FIG. 5C) into the HZO peaks reveals mostly non-monoclinic crystalline grains, suggesting either orthorhombic (ferroelectric) phase or tetragonal (anti-ferroelectric) phase. No small peak associated with minor content of thermodynamically stable monoclinic phase can be noticed. These XRD results suggest that ALD HZO thin film growth using advanced metallocene-type precursors allows for BEOL compatible process suitable for different non-volatile memory and neuromorphic computing applications.

In certain embodiments, the FTJ can be incorporated into a crossbar array or a memory unit cell. In certain embodiments, the FTJ can be incorporated into a neuromorphic computing chip or a synaptic device such as a synaptic memristor or a synaptic transistor.

An embodiment of a process for preparing and depositing the inherently ferroelectric materials descried herein using ALD. The method includes several steps that can be augmented with additional and/or optional steps. Step 1 includes providing a substrate at a deposition temperature of between approximately 265° C. and approximately 500° C., but that is preferably at or around approximately 300° C. (e.g., above approximately 285° C. and at or below approximately 300° C.) and below 340° C. Step 2 includes (i) exposing the substrate to a first precursor containing hafnium or zirconium or both hafnium and zirconium that does not decompose at the deposition temperature and (ii) purging. Step 3 includes (i) exposing the substrate to a reaction gas containing oxygen and (ii) purging. Step 4 includes (i) exposing the substrate to a second precursor containing zirconium or hafnium or both hafnium and zirconium that does not decompose at the deposition temperature and (ii) purging. Step 5 includes exposing the substrate to a reaction gas containing oxygen. Optional Step 6 includes repeating Steps 2-5 until a film of hafnium oxide and zirconium oxide of desired thickness is formed with a molar ratio between approximately 1:3 and approximately 3:1.

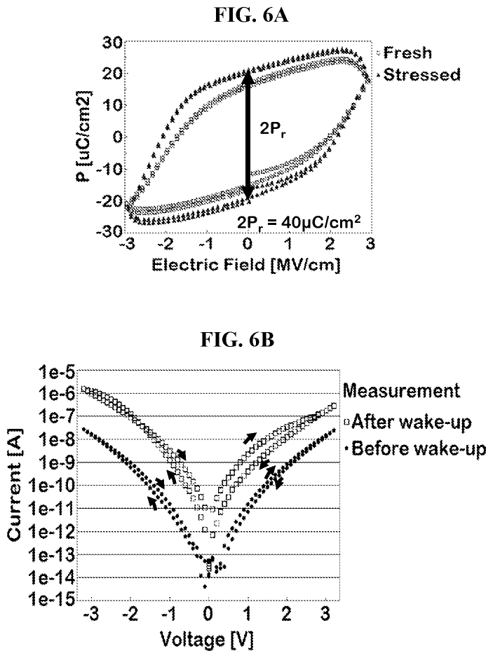

In a process of the instant disclosure, the inherently ferroelectric materials are formed and deposited as films having a substantial volume fraction of a ferroelectric phase as deposited (i.e., without further annealing and/or capping) and as measured by a phase determining technique or electrical testing known to those skilled in the art (e.g., XRD, XAS, TEM, polarization-voltage testing, piezo force microscopy, or combinations thereof). The metallocene precursors utilized and/or that can be utilized in the process of FIG. 6 include all of those disclosed and discussed above and include, in particular, (MeCp)₂Zr(Ome)Me. (MeCp)₂Hf(Ome)Me, (MeCp)₂Zr (Me)₂ and (MeCp)₂Hf (Me)₂. The reaction gas containing oxygen of Step 3 and/or Step 5 is preferably ozone. Those skilled in the art will recognize that other reaction gases can be used including those specifically described above (e.g., water, hydrogen peroxide)

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

HZO Film Growth

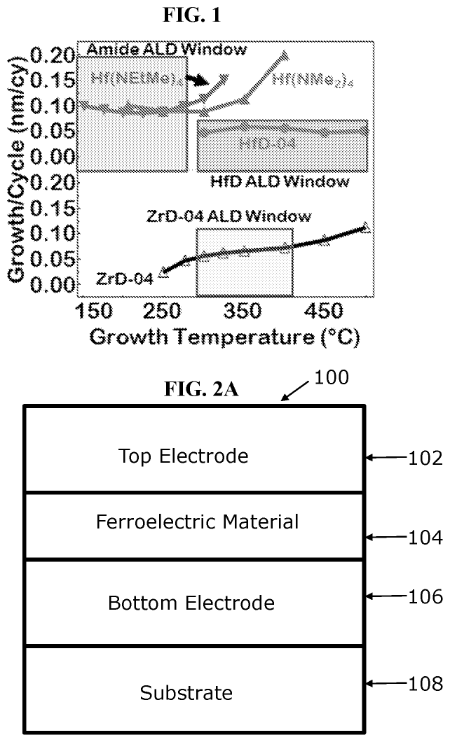

The FE HZO film is grown by atomic layer deposition at 355° C. with an exposure sequence of HfD-04 (Bis(methylcyclopentadicny l) methoxymethyl-hafnium)/ozone/ZrD-04 (Bis(methylcyclopentadienyl)methyl-zirconium metboxide)/ozone comprising one HZO supercycle. Hf-D04 and Zr-D04 are both proprietary chemicals from EMD Electronics. FIG. 1 shows that these two cyclopentadienyl precursors have ALD window at higher (300° C.-400° C.) temperatures compared with amide-type precursors, allowing for lower temperature PMA process in order to get desired HZO crystalline grains. We have deposited the films for two different ozone concentrations (4% and 20%) which was found to yield different ferroelectric properties. HfD-04 and ZrD-04 precursors were kept at an ampule temperature of 125° C. and 70° C. respectively during deposition. Different ozone concentration gives slightly different growth rate (4% ozone has slightly less growth per cycle).

### Device Fabrication

For simple metal-FE-metal (MFM) stack fabrication, we deposit W (50 nm) as the bottom electrode (BE) using a PVD process. Then, the HZO film is deposited by ALD at 325 degrees Celsius. This is followed by the top electrode (TE) (20 nm TiN or W deposited by PVD), a 2 minute PMA from 400 to 600C in N₂ ambient, followed by patterning of TE and SF₆ etch.

For the scaled device, films were deposited on a pre-manufactured test vehicle with a 300 nm diameter W plug buried in SiO₂ (FIG. 6B). The process starts with ALD HZO deposition followed by the TE deposition (50 nm TiN) by PVD, 2 min PMA at 400° C. in N₂ ambient, lithography to define TE area and a final SF₆ etch.

### Physical Characterization of HZO Film

### Large Area FTJ Device

FIGS. 5A-5B illustrate an embodiment of the HZO FTJ stack of the instant disclosure. FIG. 5A is a Cross-sectional TEM image of W (50 nm)/HZO (4.5 nm)/TiN (50 nm) after 400° C. anneal for 2 min in N₂. FIG. 5B is EELS mapping across the cross section. The bottom interfacial layer (IL) shows formation of WOₓ

The bottom (first) electrode and the top (second) electrode may be metallic or semiconducting electrodes having a thickness to ensure good conduction. In the illustrated embodiment, the top electrode comprises titanium nitride. In other embodiments, the top electrode may comprise any of titanium nitride, tungsten, nickel, ruthenium, platinum, and aluminum. In an illustrated embodiment, 50 nm thick TiN is used.

In the illustrated embodiment, the bottom electrode comprises tungsten. In other embodiments, the top electrode may comprise any of titanium nitride, tungsten, ruthenium, platinum, and aluminum. In the illustrated embodiment, 50 nm thick W is used.

The interfacial layer is created during, prior to, or after the HZO deposition. Oxidation of the W bottom electrode creates an interfacial layer comprising WOₓ. In one embodiment, the interfacial layer comprises WO₃ and an oxygen plasma pulsing step takes place prior to the deposition of the ferroelectric material. The oxygen plasma pulsing step comprises elemental oxygen (O), molecular oxygen (O₂), and ozone (O₃).

The EELS also reveals close to a 1:1 ratio between Hf and Zr. To confirm the crystallinity of HZO film XRD analysis have been performed on the same sample. FIG. 5C shows the XRD pattern of the thin HZO film. We can observe very sharp metallic W peak from the BE. However, besides the metallic W peak, we observed prominent peaks of WOₓ confirming the findings of the EELS spectra. Closer inspection (inset FIG. 5C) into the HZO peaks reveals mostly non-monoclinic crystalline grains, suggesting either orthorhombic (ferroelectric) phase or tetragonal (anti-ferroelectric) phase. No small peak associated with minor content of thermodynamically stable monoclinic phase can be noticed.

The ferroelectric layer comprises HfₓZr₁₋ₓO₂. In alternative embodiments, the ferroelectric layer may comprise HfO₂ doped with La. Y. Gd, Sr, or combinations thereof.

In the illustrated embodiment a post-metal anneal (PMA) is performed at 400 degrees Celsius for 2 minutes.

FIG. 6A illustrates the polarization-electric field plot for the inherently ferroelectric materials formed and deposited in the process illustrated in FIG. 4A as measured using a ferroelectric tester. To characterize fundamental ferroelectric properties of the material, we have carried out polarization vs electric field (P-E) measurements applying typical double bipolar triangular pulses sequence with a frequency of 10 KHz. P-E characteristics are shown in FIG. 5 for the fresh device and after a wake-up stress (+1.5V, 1 ms pulse width for 103 cycles). Fresh device shows 2Pr window close to 30 μC/cm². After mild wake-up process, the 2Pr window is improved up to 40 μC/cm². These results confirm that the use of advanced metallocene precursors (HfD-04/ZrD-04) enable BEOL compatible integration of ferroelectric thin HZO (<5 nm) without the need of PMA at higher temperatures (>=500° C.) as required when using amide-based precursors such as TEMA-Hf/TEMA-Zr.

Note that the P-E loop is not symmetric in the x-axis. This is due to the asymmetric nature of the stack created by in-situ growth of interfacial WOₓ and different metals (W and TiN) at the bottom and top interfaces, respectively.

FIG. 6B illustrates current-voltage DC sweeps of the scaled device before and after wake-up stress. FIG. 6 shows the current-voltage (I-V) characteristics for the scaled FTJ device (300 nm W plug diameter size) shown in FIG. 4B. The device initially shows very small memory window for a DC sweep up to 3V. However, after a wake-up cycling (+4.2V, 1 us pulse width (PW) for 103 cycles), the memory window opens significantly up to 10× in the low field region below 1V. The switching is repeatable and does not include any abrupt change in the current that is typically visible in filamentary RRAM switching. This suggests that the current hysteresis is due to the polarization switching of the ferroelectric materials

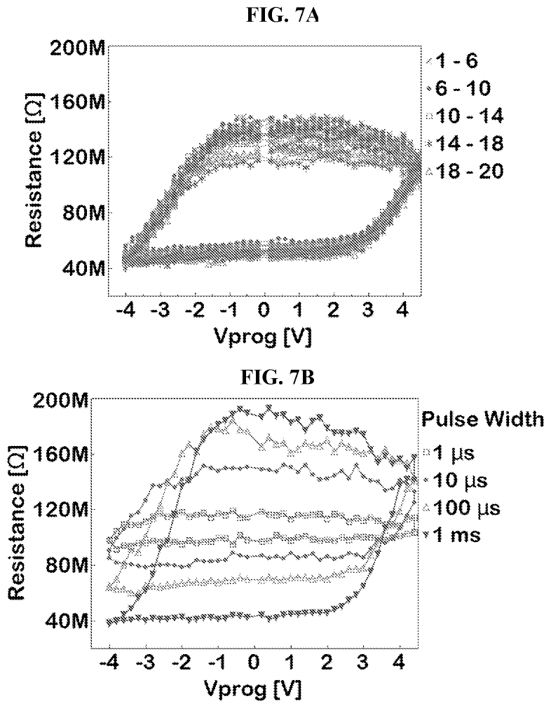

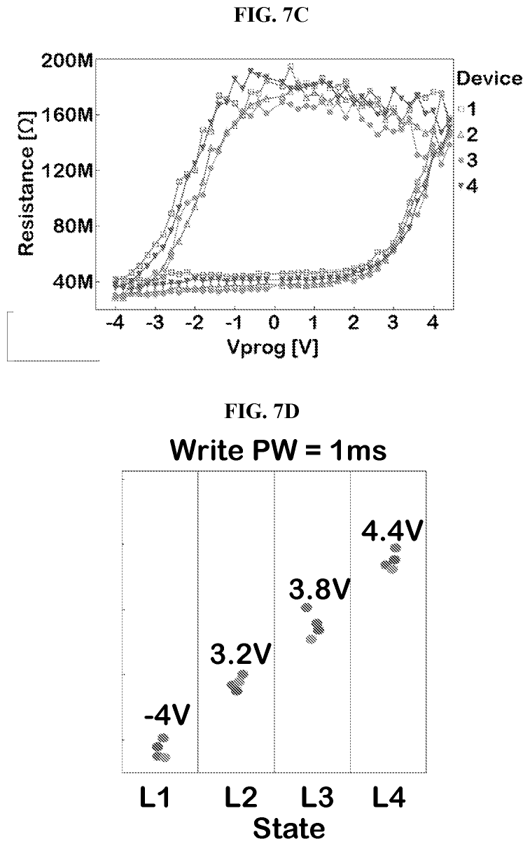

FIG. 7A illustrates resistance versus programming voltage for the scaled device and shows the R-V characteristics of one FTJ device for 20 cycles where the PW is kept at 100 us for program pulses at variable program voltages (Vprog) and for read pulses at fixed read voltage Vread =1.5V. From the R-V characteristics (FIG. 7A), we observe that the low resistance state (LRS) and high resistance state (HRS) distributions maintain a tight distribution over 20 cycles having a ˜3× memory window (6.6% and 5.9% cycle-to-cycle variability (OR/R) for HRS and LRS respectively). Moreover, the resistance window is tunable by varying the write pulse width as shown in FIG. 7(b). FIG. 7B illustrates resistance versus programming voltage for the scaled device for a different write pulse width. These results suggest that the resistance window can be modulated from ˜1.3× for 1 μs pulse to ˜5× for 1000 μs pulse. The dependence of R-V window on pulse width is due to the depolarizing field due to the incomplete polarization charge screening at the contacts. This contrasts with the filamentary breakdown in RRAM where the HRS level is dominated by the tunnel barrier formed after filament rupture and hence less dependent on the pulse width. We also observe that the resistive switching is quite gradual as the voltage amplitude varies. This suggests partial FE domain switching that can be modulated by both pulse width and pulse amplitude independently. FIG. 7C shows the R-V characteristics of 4 different device. The figure indicates low device-to-device variation and shows the uniformity of the film properties across the sample. Using different pulse amplitude, we demonstrate gradual resistive switching between 4 stable levels across 4 different devices (FIG. 7D). Tight distribution across all the 4 states is observed confirming the uniformity of the film and repeatability of the process.

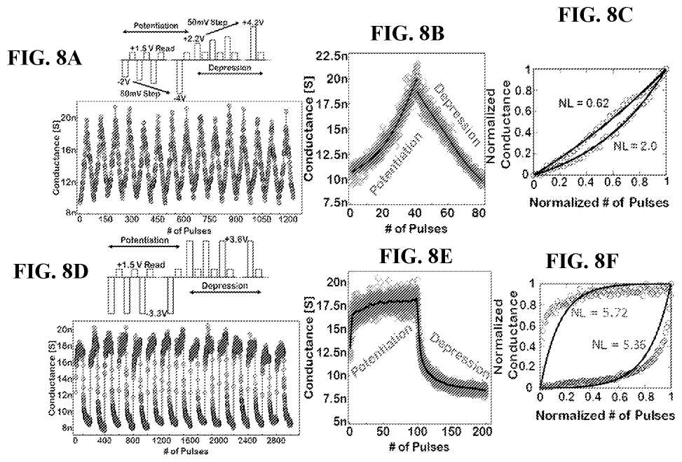

Analog switching behavior necessary for in-memory computing architectures, is demonstrated by switching the FTJ with a pulse train where the resistance/conductance changes gradually across a range higher than 2×. To maintain high linearity, we chose a pulse train of increasing pulse amplitude keeping the pulse width constant. FIG. 8A shows the potentiation and depression curves (conductance vs # of pulses during both set and reset pulses) for 15 cycles for a train of pulses of increasing amplitude (−2V to −4V for potentiation with −50 mV step, +2.2V to +4.2V for depression with 50 mV step and +1.5V for read voltage at 100 μs PW). To compute the linearity and repeatability of the analog switching, the potentiation and depression curves for 15 cycles of input pulse trains are superimposed on each other with the median response shown (FIG. 8B). We fit the median curve with model reported in shown in FIG. 8C and extract the non-linearity (NL) metric. We report an NL value of 0.62 for depression and 2.0 for potentiation, one of the best reported for FTJ compared with recent works published in literature. Similarly, we have tested the device for a pulse train of having constant pulse amplitude and width (FIG. 8D-8F). FIG. 8E shows the superimposed response from FIG. 8D, and FIG. 8F shows extraction of NL metric. In case of constant pulse testing, we used −3.3 V/100 μs for potentiation and +3.6 V/100 μs for depression. Constant pulse amplitude results in a higher non-linearity that might not be suitable for in-memory computing application. Nevertheless, it can still be switched as a multi-level digital memory that could increase the bits/cell memory density.

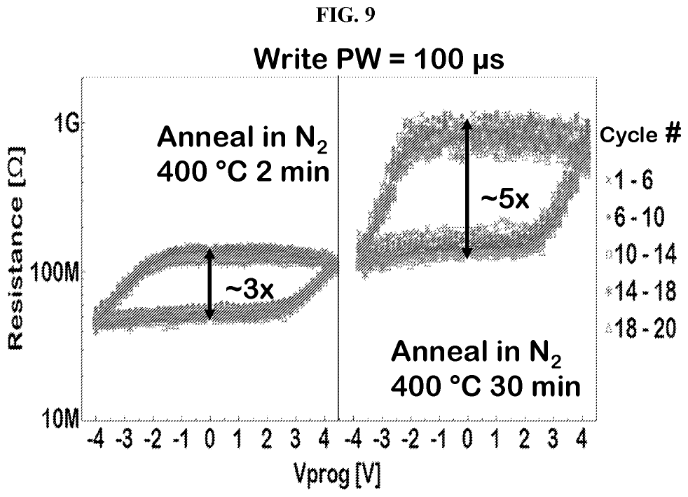

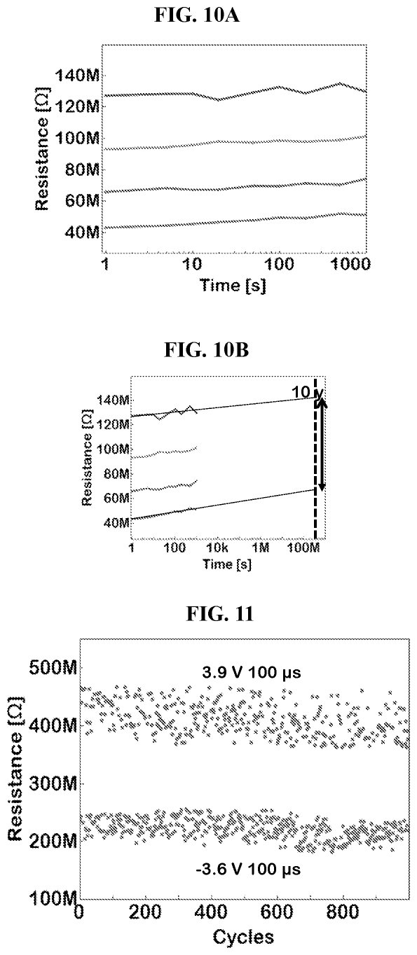

FIGS. 8A-8F illustrate conductance over number of pulses illustrating good linearity for the 4% ozone embodiment of the scaled device. FIG. 9 illustrate resistance versus voltage after different post metal anneal conditions. FIGS. 10A-10B illustrate multi-level states retention over time measured at room temperature.

FIG. 9 shows the impact of annealing conditions on the R-V window. In this figure, the write PW is kept constant at 100 μs for both the devices. Only the duration of annealing is varied, keeping the annealing temperature constant at 400° C. Moreover, FIG. 9 reveals that longer annealing of 30 min increases the memory window from 3× to 5×, which implies that longer annealing time creates larger crystallites with orthorhombic phase. To validate the reliability of our FTJ device, we have also verified the multi-level retention and endurance. In FIGS. 10A-10B, we show multilevel retention measured at RT for 103 s. Please note that in order to program 4 different resistance states we have used same conditions indicated in FIG. 7D. LRS shows slight relaxation of the FE domains suggesting potential overlapping of different states after longer time, but stable 2 level retention for up to 10 years. FIG. 11 shows 103 cycling endurance performed on our sub-μm scaled device with single pulse programming technique and read pulse after programming (−3.6V 100 μs PW to program LRS state, 3.9V 100 μs PW to program HRS state and 1.5V 100 μs PW to read different states). Stable ˜2x memory window can be obtained with low variability for both programmed states. Retention loss over time and limited endurance are two of the biggest challenges observed in literature for FTJ devices and optimization of the stack through interface engineering will be crucial to adopt this technology to enable neuromorphic hardware implemented using memristors.

A major advantage of the instant disclosure is multi-level cell demonstration without resistance drift for an FTJ. FIGS. 10A and 10B demonstrate 4 levels of resistance switching where each resistance levels were stable for 10-3 seconds. In FTJ, demonstrating multiple states is difficult because of the electric dipole relaxation, the resistance window collapse quickly. Also, multi-level switching depends on the existence of multiple domains and their partial switching.

An advantage of the instant FTJ system is simplified process flow. The illustrated FTJ stack can be fabricated without the deposition of any interfacial dielectric layer thereby eliminating one process step from the process flow.

In the instant embodiment, the interfacial layer is created during HZO deposition. Oxidation of the TiN electrode creates an interfacial layer comprising TiOₓN_{y}. An oxygen plasma pulsing step takes place prior to the deposition of the ferroelectric material. The oxygen plasma pulsing step comprises elemental oxygen (O), molecular oxygen (O₂), and ozone (O₃).

A further advantage of the instant FTJ system is a lower overall thermal budget. It is important for on-chip back-end-of-the-line (BEOL) compatible memory to be fabricated below 400C temperature in any of its process steps. Typical HZO films were deposited amorphous due to low temperature ALD process and then it requires high temperature annealing for the FE domains to be activated. The illustrated process utilizes high temperature ALD precursors that allows the films to be highly ferroelectric as deposited. Typically, a preferred deposition temperature is between 300° C.-350° C. and then 400° C. annealing is sufficient to make it highly stable. This makes the process flow BEOL compatible.

A further advantage of the instant FTJ system is faster read/write operation. Since the FTJs depend on tunneling electroresistance, the devices are high resistive compared to other non-volatile memory technologies like ReRAM and PCM in both their low resistance and high resistance states. Although this is desirable for energy dissipation point of view, too high resistance require high voltage to read causing reliability concern and slower pulses causing the read and write unreasonably slow and more prone to noise. Since we do not require any dielectric layers to create asymmetry and the films have high remnant polarization, the stack can be designed to be thin and still have sufficient FE dipole to create a memory window. This makes the illustrated FTJ stack highly scalable, both in terms of the thickness of the ferroelectric material and the area of the device.

Table illustrates FTJ Benchmark parameters of the scale device against NamLab, IBM, and Kioxia. Thermal budget is 400 degrees Celsius; FE film thickness is 4.5 nm, area is 0.09 μm², on/off ratio is ˜5, non-linearity is +0.62/−2.29, RON is 100 Mohms, read voltage is 1.5 V, LRS read current density is 1.66×10⁻³ A/cm², and multilevel retention is 4 levels (10³s at 25 degrees Celsius.

This application demonstrates a scaled FTJ fabricated with BEOL-compatible HZO process conditions that can attain analog resistance values with highly reliable device operation. Such high-performance device is enabled by high temperature ALD processes with cyclopentadienyl precursors

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

The metallocene precursors were or otherwise can be prepared according to U.S. U.S. Pat. No. 8,568,530 the contents of which is incorporated herein in its entirety.

TABLE

| | Present | NamLab | IBM | Kioxia |
|---|---|---|---|---|
| KPI | Work | Al₂O₃/HZO | WOₓ/HZO | SiO₂/HfSiO |
| Thermal Budget [° C.] | 400 | 600 | 375 | 1000 |
| FE Film Thickness [nm] | 4.5 | 12 | 4.9 | 4.5 |
| Device Area [μm²] | 0.09 | 31415 | 14400 | 0.09 |
| On/Off Ratio | ~5 | ~10 | ~7 | ~2.5 |
| Non-linearity* | +2.0/−0.62 | +0.85/−4.76 | +1.9/−4.0 | +2.2/−4.88 |
| R_{ON} [MΩ] | 100 | 1000 | 100 | 150 |
| Read Voltage [V] | 1.5 | 2 | 0.3 | 3 |
| Switching Speed [μs] | 100 | 10-100 | 50 | 2 |
| LRS Read Current | 1.66 × 10⁻³ | 6.3 × 10⁻¹⁰ | 8.3 × 10⁻¹⁰ | 2.2 × 10⁻³ |
| Density [A/cm²] | | | | |
| Multi-level retention | 4 levels | 4 levels | 3 levels | Not |
| | (>10³ s @RT) | (~10³ s @RT) | (~10⁵ s @RT) | reported |

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

1. A ferroelectric tunnel junction comprising:
a substrate;
a first electrode and a second electrode, wherein a portion of the first electrode or the second electrode has been oxidized to form an interfacial layer;
a film comprising crystalline material disposed between the first electrode and the second electrode, the crystalline material comprising hafnium oxide and zirconium oxide, wherein the crystalline material exhibits ferroelectric behavior as deposited, wherein the film has a thickness of approximately 0.2 nm to approximately 5 nm; and
a voltage source connected to the first electrode or the second electrode.

2. The ferroelectric tunnel junction of claim 1, wherein the first electrode and the second electrode are independently selected from TIN, W, Ni, Ru, Pt, and Al.

3. The ferroelectric tunnel junction of claim 1, wherein the first electrode and the second electrode are independently selected from TIN and W.

4. The ferroelectric tunnel junction of claim 1, wherein the ferroelectric tunnel junction is capable of switching between at least 4 distinct resistive states.

5. The ferroelectric tunnel junction of claim 4, wherein the at least four distinct resistive states are stable for at least 10³ seconds.

6. The ferroelectric tunnel junction of claim 1, having a memory window of between about 1.5× and about 10× in a DC domain.

7. The ferroelectric tunnel junction of claim 1, having a memory window of between about 2× and about 5×.

8. The ferroelectric tunnel junction of claim 1, capable of exhibiting ferroelectric activity.

9. The ferroelectric tunnel junction of claim 1, wherein the first electrode comprises tungsten and the second electrode comprises titanium nitride.

10. The ferroelectric tunnel junction of claim 1, wherein less than 50% of the total volume of the crystalline material constitutes a non-ferroelectric phase component.

11. (canceled)

12. The ferroelectric tunnel junction of claim 1, wherein less than 4950% of the total volume of the crystalline material constitutes a monoclinic phase component.

13. The ferroelectric tunnel junction of any claim 12, wherein less than 6040% of the total volume of the crystalline material constitutes a monoclinic phase component.

14. (canceled)

15. The ferroelectric tunnel junction of claim 1, wherein a molar ratio of hafnium oxide to zirconium oxide is between approximately 1:3 and approximately 3:1.

16. The ferroelectric tunnel junction of claim 1, wherein the crystalline material has a carbon content below approximately 6 atomic percent.

17-50. (canceled)

51. A method of creating a ferroelectric tunnel junction comprising:
(i) providing a substrate;
(ii) depositing a first electrode onto the substrate;
(iii) pulsing a plasma comprising oxygen and ozone to oxidize a portion of the first electrode to form an interfacial layer;
(iv) depositing a ferroelectric layer onto the first electrode at a deposition temperature, the step of depositing the ferroelectric layer comprising:
(a) exposing the first electrode to a first precursor that does not decompose at the deposition temperature;
(b) exposing the substrate to a first reaction gas;
(c) exposing the substrate to a second precursor that does not decompose at the deposition temperature; and
(d) exposing the substrate to a second reaction gas,
wherein one of the first precursor and the second precursor comprises zirconium and the other of the first precursor and the second precursor comprises hafnium; and
(v) depositing a second electrode onto the ferroelectric layer.

52. The method of claim 51, wherein the first reaction gas and the second reaction gas are each independently a gas containing one or more of oxygen, water, hydrogen peroxide and nitrous oxide.

53. The method of claim 51, wherein the first reaction gas and the second reaction gas are each independently a gas containing oxygen, a gas containing ozone, or a gas containing water.

54. The method of claim 51, wherein an annealing step is conducted at a temperature greater than or equal to about 350 degrees Celsius.

55. The method of claim 51, wherein no process steps take place at a temperature greater than about 400 degrees Celsius.

56. The method of claim 51, wherein no interfacial layer is deposited between the ferroelectric layer and the first electrode or between the ferroelectric layer and the second electrode.

57. The method of claim 51, wherein the first reaction gas or the second reaction gas comprises ozone delivered a volumetric fraction of between about 2% and about 50%.

58. The method of claim 51, further comprising an ozone pulsing step prior to depositing the second electrode.

59. The method of claim 51, wherein the ozone pulsing step delivers a gas stream comprising between about 2% and about 50% of ozone by volume.

60. The method of claim 51, wherein the ferroelectric layer exhibits remanent polarization without additional thermal processing.

61. The method of claim 51, wherein the deposited ferroelectric I has a remanent polarization (Pr) of greater than 8 μC/cm² or a total loop opening of greater than 16 μC/cm².

62. The method of claim 51, wherein the first electrode comprises TiN and the interfacial layer comprises TiOₓN_{y}, wherein x and y are integers.

63. The method of claim 51, wherein the first electrode comprises Tungsten (W) and the interfacial layer comprises WOₓ, wherein x is a non-negative integer.

64. The method of claim 51, wherein the first electrode comprises Ruthenium (Ru) and the interfacial layer comprises RuOₓ, wherein x is a non-negative integer.

65. The method of claim 51, wherein the first electrode comprises tungsten and the second electrode comprises titanium nitride.

66. The method of claim 54, wherein the annealing step is conducted at a temperature lower than or equal to about 400 degrees Celsius.

67. (canceled)

68. (canceled)

69. (canceled)

70. The ferroelectric tunnel junction of claim 1 having a critical dimension of about 300 nm or less.
